(19) United States
(12) Patent Application Publication
(10) Pub. No.: US 2025/0005215 A1
(43) Pub. Date: Jan. 2, 2025

(54) PROCESSING METHOD AND ELECTRONIC DEVICE

(71) Applicant: Lenovo (Beijing) Limited, Beijing (CN)

(72) Inventors: Peng WANG, Beijing (CN); Qigang WANG, Beijing (CN); Yuwei SHANG, Beijing (CN)

(21) Appl. No.: 18/544,817

(22) Filed: Dec. 19, 2023

(30) Foreign Application Priority Data
Dec. 31, 2022 (CN) 202211738248.9

(51) Int. Cl. G06F 30/13; G06F 30/27

(52) U.S. Cl. CPC G06F 30/13; G06F 30/27

(57) ABSTRACT

A processing method includes obtaining a model constraint condition, determining at least one target model architecture satisfying the model constraint condition from a constructed model architecture collection, and determining a pre-trained model parameter of the target model architecture according to the pre-trained model parameter of the corresponding seed model architecture to identify the target model architecture with the pre-trained model parameter. The model architecture collection includes at least one seed model architecture with a pre-trained model parameter and a non-seed model architecture without a pre-trained model parameter obtained by adjusting the seed model architecture. The target model architecture is one of the seed model architecture or the non-seed model architecture.

### CROSS-REFERENCE TO RELATED APPLICATION

The present disclosure claims priority to Chinese Patent Application No. 202211738248.9, filed on Dec. 31, 2022, the entire content of which is incorporated herein by reference.

### TECHNICAL FIELD

The present disclosure relates to the artificial intelligence technology field and, more particularly, to a processing method and an electronic device.

### BACKGROUND

Automatic deep learning is able to quickly generate a neural network model centered on data in different industry scenarios and user constraints and is a technical solution with great potential. The current automatic deep learning technology includes the following two problems.

First, search complexity of a model architecture is high and searching consumes massive computation power. In many cases, the effectiveness of randomly searching the combination space is minimal.

Second, the searched architecture model does not have a pre-training weight. A large amount of annotated data and training calculations are required for training the model, which causes difficulty for a downstream task application.

### SUMMARY

An aspect of the present disclosure provides a processing method. The method includes obtaining a model constraint condition, determining at least one target model architecture satisfying the model constraint condition from a constructed model architecture collection, and determining a pre-trained model parameter of the target model architecture according to the pre-trained model parameter of the corresponding seed model architecture to obtain the target model architecture with the pre-trained model parameter. The model architecture collection includes at least one seed model architecture with a pre-trained model parameter and a non-seed model architecture without a pre-trained model parameter obtained by adjusting the seed model architecture. The target model architecture is one of the seed model architecture or the non-seed model architecture.

An aspect of the present disclosure provides an electronic device, including a processor and a memory. The memory stores at least one computer instruction collection that, when called and executed by the processor, causes the processor to obtain a model constraint condition, determine at least one target model architecture satisfying the model constraint condition from a constructed model architecture collection, and determine a pre-trained model parameter of the target model architecture according to the pre-trained model parameter of the corresponding seed model architecture to obtain the target model architecture with the pre-trained model parameter. The model architecture collection includes at least one seed model architecture with a pre-trained model parameter and a non-seed model architecture without a pre-trained model parameter obtained by adjusting the seed model architecture. The target model architecture is one of the seed model architecture or the non-seed model architecture.

An aspect of the present disclosure provides a computer readable storage medium storing a computer instruction set that, when executed by a processor, causes the processor to:

### BRIEF DESCRIPTION OF THE DRAWINGS

FIG. 1 illustrates a schematic flowchart of a processing method according to some embodiments of the present disclosure.

FIG. 2 illustrates a schematic diagram showing a construction process of a sub-collection in a module architecture collection according to some embodiments of the present disclosure.

FIG. 3 illustrates a schematic diagram showing a determination process of a pre-training model parameter of a target model architecture according to some embodiments of the present disclosure closure.

FIG. 4 illustrates a schematic flowchart of an automatic architecture search phase according to some embodiments of the present disclosure.

FIG. 5 illustrates a schematic flowchart of a weight pre-heat phase according to some embodiments of the present disclosure.

FIG. 6 illustrates a schematic structural diagram of a processing apparatus according to some embodiments of the present disclosure.

FIG. 7 illustrates a schematic structural diagram of an electronic device according to some embodiments of the present disclosure.

### DETAILED DESCRIPTION OF THE EMBODIMENTS

The technical solution of embodiments of the present disclosure is described in detail in connection with the accompanying drawings of embodiments of the present disclosure. Described embodiments are merely some embodiments of the present disclosure, not all embodiments. Based on embodiments of the present disclosure, all other embodiments obtained by those ordinary skills in the art without creative effort should be within the scope of the present disclosure.

The present disclosure provides a processing method and an electronic device for solving at least some technical problems faced by the current automated deep learning technology. The processing method can be applied to, but is not limited to, an electronic device under a plurality of general-purposed or special-purposed computation apparatus environments or configurations, such as a personal computer, a server computer, a handheld device or a portable device, a tablet device, a multi-processor apparatus, etc.

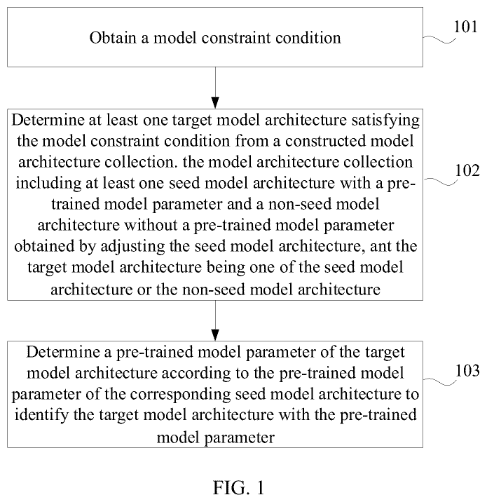

FIG. 1 illustrates a schematic flowchart of a processing method according to some embodiments of the present disclosure. The processing method of embodiments of the present disclosure includes the following processes.

At 101, a model constraint condition is obtained.

In the present disclosure, a model architecture collection can be created. The model architecture collection can include at least one seed model architecture having a pre-trained model parameter and a non-seed model architecture without the pre-trained model parameter obtained by adjusting the seed model architecture.

A plurality of seed model architectures in the model architecture collection can correspond to different specifications, and the corresponding specifications are in a discrete distribution state. The specification of the model architecture can include, but is not limited to, any one specification parameter of a calculation amount (i.e., the calculation amount of the model architecture processing singular input data), a parameter quantity, inference rate, accuracy, etc., or a characterization performed on any parameter combination of the plurality of specification parameters. For example, parameter values of the various specification parameters of the model architecture can be normalized and weighted, and the specification of the model architecture can be characterized based on the weighted result.

The model parameter can include weights of network layers of the model, i.e., model weights. The pre-trained model parameter can be a trained model weight obtained by training the model architecture in advance.

By creating the model architecture collection including the seed model architecture and the non-seed model architecture, the model architecture collection with a continuous specification can be created. That is, the model architectures in the model architecture collection can correspond to different specifications, and the corresponding specifications can be in a continuous distribution state.

In embodiments of the present disclosure, by obtaining the plurality of seed model architectures having the pre-trained model parameters, and by adjusting the model attributes of the seed model architecture and/or applying a corresponding architectural operation on the seed model architecture, the non-seed model architecture corresponding to the seed model architecture can be obtained. The seed model architectures and the non-seed model architectures corresponding to the seed model architectures can form the model architecture collection. That is, a plurality of model weights obtained through the pre-training can be obtained, and a plurality of model architectures with different specifications and a same functional type can be used as the discrete model point, i.e., the seed model architectures. By adjusting each seed model architecture of the seed model architectures, the non-seed model architecture corresponding to each seed model architecture can be obtained.

In embodiments of the present disclosure, the seed model architectures and the non-seed model architectures in the model architecture collection can have the same functional type.

For example, the model architectures in the collection can be configured for image classification or target detection (e.g., device defect detection based on image processing). The model architectures in the model architecture collection can be a deep learning neural network model architecture of any required type, e.g., RedNet50 or other neural network model architecture, to form a continuous neural network model group that can be configured to process a specific operation and satisfy different specification requirements.

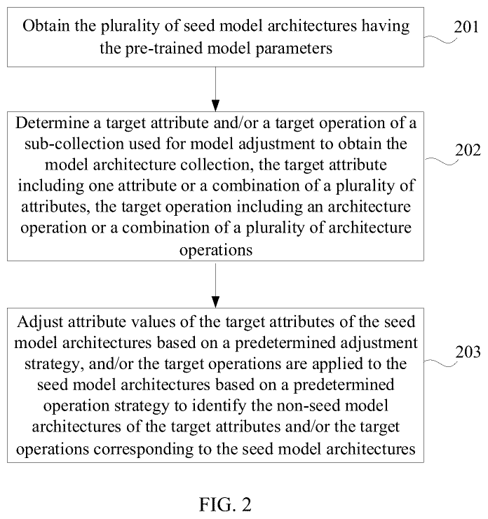

In some embodiments, the model architecture collection can include a plurality of sub-collections. FIG. 2 illustrates a schematic diagram showing a construction process of a sub-collection in a module architecture collection according to some embodiments of the present disclosure.

At 201, the plurality of seed model architectures having the pre-trained model parameters are obtained.

At 202, a target attribute and/or a target operation of a sub-collection used for model adjustment to obtain the model architecture collection is determined. The target attribute includes one attribute or a combination of a plurality of attributes. The target operation includes an architecture operation or a combination of a plurality of architecture operations.

The attribute can be the attribute of the model architecture and include, but is not limited to, a number of network layers, a number of channels of each layer, a size of a convolution kernel, a number of attention heads, and a number of in and out neurons of a fully connected layer. In some embodiments, a model attribute library including but not limited to the above attributes can be established in advance. Thus, one or more attributes can be selected from the library when necessary. Then, the target attribute that is used to perform the model adjustment on the seed model architecture to obtain the sub-collection of the model architecture collection can be obtained.

An architecture operation can refer to an operation that can be applied to the model architecture, including but not limited to single or multiple operation operators, such as interpolation, scaling, layer swapping, and adding/decreasing high-speed connections. In some embodiments, an architecture operation operator library including but not limited to the supported various types of operation operators can be established in advance. Thus, a target operation that is used to perform the model adjustment on the seed model architecture to obtain a sub-collection of the model architecture collection can be obtained.

At 203, attribute values of the target attributes of the seed model architectures are adjusted based on a predetermined adjustment strategy, and/or the target operations are applied to the seed model architectures based on a predetermined operation strategy to obtain the non-seed model architectures of the target attributes and/or the target operations corresponding to the seed model architectures.

The seed model architectures and the non-seed model architectures of the target attributes and/or the target operations corresponding to the seed model architectures can form a sub-collection of the model architecture collection. The non-seed model architectures of different sub-collections can correspond to different target attributes and/or different target operations, and the specifications of the model architectures included in any sub-collection can be in a continuous distribution state.

In some embodiments, the predetermined adjustment strategy can include continuously and repeatedly adjusting the attribute values of the target attributes (one attribute or a collection of a plurality of attributes) of the seed model architectures according to a determined precision step for the selected target attribute. After each adjustment, a non-seed model architecture corresponding to the seed model architecture can be obtained to achieve the continuous effect of the model specification as much as possible from the continuous adjustment aspect for the attribute values. The predetermined operation strategy can include performing the target operation on a plurality of different layers or layer combinations of the model in a traverse manner for the selected target operation, e.g., one selected architecture operation operator or the plurality of selected architecture operation operators. After each time of performing the target operation on each layer or each layer combination of the seed model architecture, one non-seed model architecture corresponding to the seed model architecture can be obtained. By traversing all cases, the specifications of the model group can form a continuous effect in the model architecture space as much as possible.

By selecting different target attributes and/or target operations for the seed model architectures in the model architecture collection multiple times, and performing the adjustment processing on the seed model architectures based on different selected target attributes and/or target operations, different sub-collections of the model architecture collection can be obtained. Thus, the non-seed model architectures of the different sub-collections can correspond to different target attributes and/or different target operations.

In some embodiments, a plurality of dominant discrete model points can be selected as a plurality of seed model structures, and the model architecture collection can be created by performing the model adjustment processing on the plurality of dominant discrete model points. In some embodiments, the plurality of dominant discrete model points can be models that are pre-trained and verified by the industry, e.g., a plurality of model architectures with a discrete specification distribution and a relatively balanced dispersion that have pre-trained model parameters (e.g., model weights) after the pre-training and are verified by the model specification (e.g., the calculation amount/parameter quantity/inference rate/precision/accuracy of the model). For example, in a series of classic neural network models, the model architecture collection can be constructed based on the plurality of dominant discrete model points that are pre-trained and verified by the industry and satisfy the above features to perform the required model architecture search in the search space of the dominant discrete model points in the architecture space to solve the problems of the high complexity of the model search and traversing excessive invalid architecture sub-spaces.

Based on the model architecture collection, when the user needs to obtain a model architecture of a corresponding specification based on operation application requirements (e.g., further model training based on the existing model architecture or application of the existing model), a corresponding model constraint condition can be input or submitted to search the target model architecture satisfying the condition in the created model architecture collection.

The model constraint condition can be used to indicate the target specification of the user for the model architecture. The required target specification can be characterized by setting the required calculation amount, the parameter quantity, the inference rate, the precision, and the accuracy value of the mode.

At 102, at least one target model architecture satisfying the model constraint condition is determined from the created model architecture collection.

An execution body of the method of the present disclosure, e.g., the electronic device, can correspondingly obtain the model constraint condition input by the user and perform the model architecture search in the model architecture collection according to the model constraint condition to obtain the at least one target model architecture satisfying the model constraint condition.

The target model architecture can be one of the seed model architecture or the non-seed model architecture.

In some embodiments, when performing the model architecture search based on the model constraint condition, model architectures with the matching degrees between the corresponding specifications and the target specifications indicated by the model constraint condition belonging to first k matching degrees in a matching degree descending sequence can be determined to obtain k target model architectures, where k is an integer not smaller than 1. That is, according to the needs, a model architecture with the corresponding specification closest to the target specification indicated by the model constraint condition or a plurality of model architectures with relatively high similarities between the corresponding specification and the target specification can be searched in the model architecture collection, which can be determined as needed and is not limited. “Closest” can refer to that the corresponding specification is slightly different from but not equal to the target specification, which can be determined according to the matching situation between the actual specification of the model architectures in the model architecture collection and the target specification required by the model constraint condition and is not limited.

When the model architecture collection includes a plurality of sub-collections, searching the at least one target model architecture satisfying the model constraint condition in the model architecture collection can include obtaining model architecture samples sampled from the current sub-collection and obtaining the model architectures included in the current replay pool as the candidate model architecture.

When the model architecture collection includes a plurality of sub-collections, the model architecture search can be performed on some or all sub-collections of the model architecture collection based on the model constraint condition.

In some embodiments of the present disclosure, the replay pool can be pre-created. The replay pool can be initially empty and configured to store the k model architectures matching the model constraint condition the most in the current search progress during the search process of the sub-collections. That is, when the replay pool is not empty, the number of the model architectures in the replay pool can be k and can record the model architectures with the matching degree between the specification corresponding to the current search progress and the target specification indicated by the model constraint condition belonging to the first k matching degrees in the matching degree descending sequence.

When performing the model architecture search based on the model constraint condition for the model architecture collection, a search can be performed on the sub-collections in sequence, and the model architectures in the replay pool can be gradually optimized based on the search of the current sub-collection and the target verification. To reduce the search complexity and calculation power, in some embodiments, when performing a search on the sub-collection, sampling can be first performed on the current sub-collection that is to be searched. Then, the model architecture samples obtained from sampling can participate in searching, the model architectures that are not sampled in the current sub-collection may not participate in searching.

Further, when performing searching and target verification on the current sub-collection that is to be searched, and optimizing the replay pool, the model architecture samples sampled from the current sub-collection can be obtained, and the model architectures included in the current replay pool can be obtained as the candidate model architectures to participate in the current processing.

When the current sub-collection is the first sub-collection that is searched, the replay pool can be in an empty state. The model architecture samples sampled from the current sub-collection can be correspondingly used as the candidate model architectures.

When the model architecture collection includes a plurality of sub-collections, searching the at least one target model architecture satisfying the model constraint condition in the model architecture collection can further include determining the model architectures with the matching degree between the corresponding specification and the target specification indicated by the model constraint condition belonging to the first k matching degrees in the matching degree descending sequence from the candidate model architectures and updating the determined k model architectures to the replay pool.

Then, determining the model architectures with the matching degree between the corresponding specification and the target specification indicated by the model constraint condition belonging to the first k (topk) matching degrees in the matching degree descending sequence from the candidate model architectures and updating the determined k model architectures to the replay pool can mean that, for the k model architectures previously stored in the replay pool, if the matching degree of between the corresponding specification and the target specification still belongs to topk after the current processing, the k model architectures can be maintained in the replay pool, if not, the k model architectures can be removed from the replay pool, and other model architectures with the matching degrees belonging to topk determined in the current processing can be used to replace the previous k model architectures. Thus, the replay pool can be optimized based on the search and verification performed on the current sub-collection.

In some embodiments, a loss function can be created according to the operation target of the specification parameter such as the model parameter quantity, the model calculation amount, the inference rate, the precision, and the accuracy rate. Model architecture samples that can better satisfy the operation target (i.e., for the loss function causing the model to have lower loss in the parameter quantity/model calculation amount/inference rate/precision/accuracy rate) can be searched in the model architecture samples obtained by sampling the current sub-collection using the optimization method. The target verification can performed on the k model architectures in the replay pool. Based on the verification, k model architectures that can better satisfy the operation target can be selected from the candidate model architectures formed by the model architecture samples and current k model architectures stored in the replay pool (the replay pool being empty initially) as the current optimal k model architectures to be updated to the replay pool. Moreover, model architectures except the current optimal k model architectures in the replay pool can be removed to optimize the k model architectures in the replay pool.

When the model architecture collection includes a plurality of sub-collections, searching the at least one target model architecture satisfying the model constraint condition in the model architecture collection can further include determining a next sub-collection, updating the current sub-collection as the next sub-collection, and switching to the step of obtaining the model architecture samples sampled from the current sub-collection and obtaining the model architectures included in the current replay pool to iteratively update the model architectures in the replay pool until the iteration ending condition is satisfied and the model architectures in the replay pool can be used as the target model architectures.

Then, a next sub-collection that is to be searched can be determined. Based on the iterative idea, the next sub-collection can be used at a current sub-collection that is to be searched. Based on this, the processing can be started for the new current sub-collection (sampling, searching, and replay pool optimization) until the iteration ending condition is satisfied. Then, the k model architectures in the replay pool can be used as k optimal model architectures satisfying the model constraint condition, and the k optimal model architectures can be further used as the target model architectures.

The iteration ending condition can include but is not limited to any one of completing the searching on all the sub-collections in the model architecture collection and the replay pool optimization based on the searching, a number of times of the iterative processing reaching a predetermined number of times, or a time length of the iterative processing reaching a determined time length.

In some embodiments, in a process of processing the sub-collections, when the sub-collection that is to be processed is determined each iteration, a next sub-collection that is to be processed can be obtained directly from the created sub-collections during iteration based on the creation of the to-be-processed sub-collections required in the sub-collection creation process or all the sub-collections of the pre-created model architecture collection, which is not limited here.

At 103, the pre-trained model parameter of the target model architecture is determined according to the pre-trained model parameter of the corresponding sub-model architecture to obtain the target model architecture having the pre-trained model parameter.

The number of the target model architectures can one or multiple, which is determined as needed. Each target model architecture can be one of the seed model architecture or the non-seed model architecture.

When a plurality of target model architectures are included, the plurality of target model architectures can all be the seed model architectures or all be non-seed model architectures, or some of the plurality of target model architectures can be the seed model architectures and the rest of the plurality of target model architectures can be the non-seed model architectures, which is subject to the actual search situation.

When the target model architecture is a seed model architecture, the searched seed model architecture satisfying the model constraint condition can be directly used as the target model architecture. Correspondingly, the pre-trained model parameter of the searched seed model architecture can be directly determined as the pre-trained model parameter of the target model architecture.

When the target model architecture is a non-seed model architecture, a seed model architecture satisfying the matching condition with the target model architecture can be determined from the seed model architectures of the model architecture collection and can be used as a reference model architecture of the target model architecture. Based on the pre-trained model parameter of the reference model architecture, the pre-trained model parameter of the target model architecture can be determined.

In some embodiments, the matching condition can include that the corresponding specifications of the seed model architectures are closest to the specification of the target model architecture.

When the target model architecture is a non-seed modal architecture, the seed model architecture with the specification closest to the specification of the target model architecture can be determined from the seed model architectures of the model architecture collection as the reference modal architecture of the target model architecture.

The closest can include left closest, right closest, or both left closest and right closest, which is not limited. A specification of a seed model architecture being left closest to the specification of the target model architecture can include that the specification of the seed model architecture is smaller than the specification of the target model architecture, and the seed model architecture of the seed model architectures with the specifications smaller than the specification of the target model architecture has the specification closest to the specification of the target model architecture. Correspondingly, a seed model architecture being right closest to the specification of the target model architecture can include that the specification of the seed model architecture is greater than the specification of the target model architecture, and the specification of the seed model architecture out of the seed model architectures with the specifications greater than the specification of the target model architecture is closest to the specification of the target model architecture.

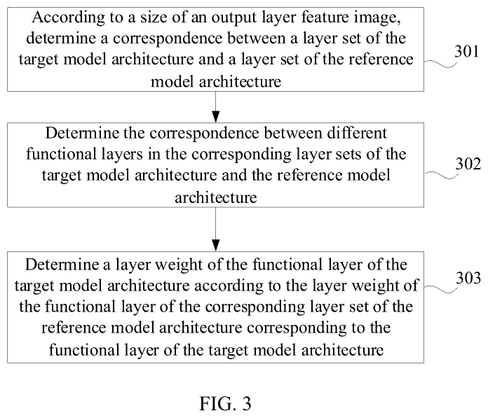

By determining the reference model architecture of the target model architecture, as shown in FIG. 3, the pre-trained model parameter of the target model architecture is determined based on the pre-trained model parameter of the reference model architecture through the following processes.

At 301, according to a size of an output layer feature image, a correspondence between a layer set of the target model architecture and a layer set of the reference model architecture is determined.

A layer set of a model architecture can be a combination of a plurality of functional layers that is capable of completing one-time sampling in the model architecture, which includes but is not limited to a combination of corresponding layers of an attention layer, a convolution layer, a full connection layer, and an output layer. The sampling can include upper sampling and lower sampling.

In embodiments of the present disclosure, according to the layer sets of the target model architecture and the reference model architecture, a matching operation of the layer sets between the models (the target model architecture and the reference model architecture) can be performed on the similarity between the sizes of the feature images obtained after completing one time of lower sampling or upper sampling for the same input object (e.g., the same sampling image) to establish a model mapping of the layer sets to determine the correspondence between the layer set of the target model architecture and the layer set of the reference model architecture. In some embodiments, two layer sets of different layer sets between the models (the target model architecture and the reference model architecture) that output feature images with the closest sizes can be matched to each other. The two layer sets can be determined as the layer sets corresponding to the target model architecture and the reference model architecture.

At 302, the correspondence between different functional layers in the corresponding layer sets of the target model architecture and the reference model architecture is determined.

Then, the correspondence between different functional layers of the corresponding layer sets of the target model architecture and the reference model architecture can be further determined. For example, when the numbers of functional layers of the corresponding layer sets corresponding to the target model architecture and the reference model architecture are the same, the same functional layers in the corresponding layer sets of the target model architecture and the reference model architecture can be directly used as the functional layers with the correspondence. When the numbers of the functional layers of the corresponding layer sets of the target model architecture and the reference model architecture are different, one-to-multiple or multiple-to-one mapping of the functional layers of the corresponding layer sets can be created based on the functional relevance of the functional layers between the corresponding layer sets.

At 303, a layer weight of the functional layer of the target model architecture is determined according to the layer weight of the functional layer of the corresponding layer set of the reference model architecture corresponding to the functional layer of the target model architecture.

Based on the above processing, according to the weight of the functional layer of the corresponding layer set of the reference model architecture corresponding to the functional layer of the target model architecture, the layer weight of the functional layer of the target model architecture can be determined. For the functional layer of the target model architecture, one or more operations of but are not limited to interpolation, abduction, downsampling, upsampling+random initialization, and sampling+tiling can be used to process the layer weight of the functional layer of the corresponding layer set of the reference model architecture corresponding to the functional layer of the target model architecture to obtain the layer weight of the functional layer of the target model architecture. The layer weights of the functional layers of different layer sets of the target model architecture can form the pre-trained model parameters of the target model architecture.

Subsequently, according to the actual needs, model training can be further performed on the target model architecture having the pre-trained model parameters (e.g., the model weights), or the target model architecture having the pre-trained model parameters can be directly used to perform the required operation processing, e.g., perform device defect detection based on the image processing.

According to the above technical solution, in the processing method of the present disclosure, the model architecture collection can be pre-created. The model architecture collection can include at least one seed model architecture having the pre-trained model parameter and a non-seed model architecture without the pre-trained model parameter obtained by adjusting the seed model architecture. Then, the model constraint condition can be obtained, and the at least one target model architecture (the target model architecture being one of the seed model architecture or the non-seed model architecture) satisfying the model constraint condition can be determined from the created model architecture collection. The pre-trained model parameter of the target model architecture can be determined according to the pre-trained model parameter of the corresponding seed model architecture to obtain the target model architecture with the pre-trained model parameter.

In the present disclosure, the created model architecture collection can include the seed model architecture having the pre-trained model parameter and the non-seed model architecture without the pre-trained model parameter. Thus, the model parameter of any searched target model architecture from the model architecture collection can be quickly determined according to the scaffolding discrete model points and the trained model parameters, which can greatly reduce the annotation data amount and the training calculation amount required by the target model architecture without bringing a large amount of early-stage operations, accelerate the processing progress of the downstream tasks, and solve at least some technical problems of the current automated deep learning technology.

In addition, by creating the model architecture collection based on the dominant discrete model points in the present disclosure, the required model architecture can be searched in the search space of the dominant discrete model points in the architecture space. Thus, the problems of the high model search complexity and the traversing of the excessive invalid architecture sub-spaces can be solved.

Embodiments of the present disclosure provide an application example of the processing method.

In some embodiments, the initial model points can be pre-determined in the architecture space. The initial model points can be a plurality of dominant discrete model points with different specifications under the classic neural network model series, which can be referred to as Seeds, i.e., the seed model architectures. Each Seed can have a pre-trained weight. A model attribute library including the number of the network layers, the number of channels of each layer, the size of the convolution kernel, the number of the attention heads, and the number of in and out neurons of a fully connected layer can be created. Moreover, an architecture operation operator library including one or multiple operation operators such as the interpolation, scaling, layer swapping, and adding/decreasing high-speed connections can be created. In addition, the replay pool can be created. The replay pool (each time performing the processing process corresponding to the model constraint condition input by the user) can be initially set to empty.

In some embodiments, the implementation of the processing method of the present disclosure can include two phases such as the architecture search phase and the architecture weight pre-heating phase.

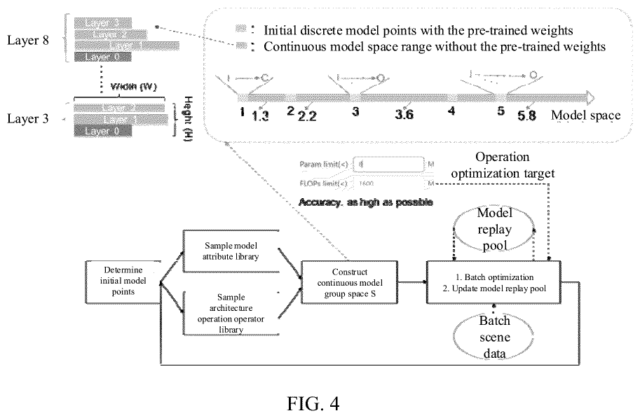

In the architecture search phase, FIG. 4 illustrates a schematic flowchart of an automatic architecture search phase according to some embodiments of the present disclosure. The architecture search phase can include the following processes.

At 21, N attributes (Attrs) are randomly extracted from the pre-created model attribute library, and M one or multiple operations (Ops) are extracted from the architecture operation operator library, where N and M are integers not smaller than 1.

In some embodiments, when the model constraint condition input by the user is received, or each time the iteration is triggered subsequently, N attributes Attrs can be randomly extracted from the pre-created model attribute library, and M single or multiple operations Ops can be simultaneously extracted from the operation operator library.

At 22, based on the Seeds model architecture, the change of the Attrs is created based on the pre-determined adjustment strategy, and combination operations Ops are applied to the

Seeds model architecture based on the predetermined operation strategy. Based on the process, a continuous model group space S corresponding to the Seeds model is created as the current sub-collection that is to be processed in the model architecture collection.

For the continuous model group space S, reference can be made to the model space example shown in FIG. 4.

At 23, in space S, the loss function is created according to the operation target of the specification parameter such as the model parameter quantity, the model calculation amount, the inference rate, the precision, and the accuracy. The optimization method is used to search for the model architecture that better satisfies the operation target of the loss function in the sample model architecture of the current sub-collection. Meanwhile, the target verification is performed on the k model architectures of the replay pool based on the loss function to select k model architectures that are currently optimal from the sample model architectures of the current sub-collection and the existing model architectures in the replay pool (the replay pool is initially empty) to optimize and update the replay pool.

The optimization method can be a differentiable optimization or reinforcement learning method.

At 24, the method includes looping to step 21 to iterate the processing process of steps 21 to 24 to continuously create the required sub-collections. The replay pool is optimized based on the processing of the plurality of sub-collections until the iteration is performed a plurality of times to obtain the k model architectures in the optimized replay pool as the k target model architectures satisfying the model constraint condition.

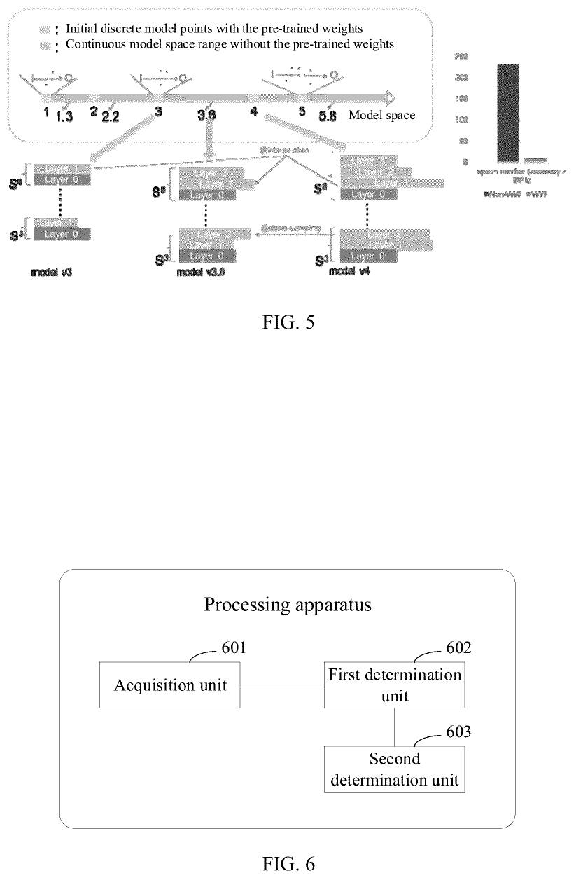

In the architecture weight pre-heat phase, FIG. 5 illustrates a schematic flowchart of the weight pre-heat phase according to some embodiments of the present disclosure. The architecture weight pre-heat operations of step 31 to step 33 are performed on each target model architecture A of the searched k target model architectures.

At 31, if each target model architecture A is a Seed model architecture, the pre-trained parameter of the Seed model architecture is directly used as the pre-trained parameter of the target model architecture A. If each target model architecture A is a non-seed model architecture, a left closest seed model architecture and/or a right closest seed model architecture corresponding to the target model architecture A are determined based on the model specification as the reference model architecture of the target model architecture A.

For example, for the target model architecture A with specification 1.3 shown in FIG. 5, the left closest seed model architecture with specification 1 and/or the right closest seed model architecture with specification 2 are used as the reference model architectures of the target model architecture A.

At 32, based on the size of the output layer feature image, the search matching operation of the layer sets is automatically performed on the target model architecture A and the reference model architecture of the target model architecture A to create the mapping between the models (the target model architecture A and the reference model architecture of the target model architecture A) of the layer sets to further establish the mapping between the models of the functional layers in the corresponding layer sets that have the mapping relationship.

At 33, for the functional layer of the target model architecture A, the operation is performed on the weight of the functional layer in the reference model architecture of the target model architecture A corresponding to the functional layer of the target model architecture A by selecting one or more operation methods of the interpolation, interpolation, abduction, downsampling, upsampling +random initialization, and sampling +tiling from the pre-heat operation operator library. The weight obtained after the operation is used as the weight of the functional layer of the target model architecture A to pre-heat the weight of the functional layer of the target model architecture A.

The layer weights of the functional layers of different layer sets of the target model architecture can form the pre-trained model parameters of the target model architecture.

Embodiments of the present disclosure further provide a processing apparatus. As shown in FIG. 6, the apparatus includes an acquisition unit 601, a first determination unit 602, and a second determination unit 603.

The acquisition unit 601 can be configured to obtain the model constraint condition.

The first determination unit 602 can be configured to determine at least one target model architecture satisfying the model constraint condition from the created model architecture collection. The model architecture collection can include at least one seed model architecture having the pre-trained model parameter and the non-seed model architecture without the pre-trained model parameter obtained by adjusting the seed model architecture. The target model architecture can be one of the seed model architecture and the non-seed model architecture.

The second determination unit 603 can be configured to determine the pre-trained model parameter of the target model architecture according to the pre-trained model parameter of the corresponding seed model architecture to obtain the target model architecture having the pre-trained model architecture.

In some embodiments, the apparatus can further include a model creation unit.

The model creation unit can be configured to obtain a plurality of seed model architectures having the pre-trained model parameters and adjusting the model attribute of the seed model architecture and/or applying the corresponding architecture operation on the seed model architecture to obtain the non-seed model architecture corresponding to the seed model architecture. The seed model architectures and the non-seed model architectures corresponding to the seed model architectures can form the model architecture collection.

In some embodiments, the model architecture collection can include a plurality of sub-collections. The model creation unit creating the sub-collections can further include obtaining the plurality of seed model architectures having the pre-trained model parameters and determining the target attribute and/or the target operation used for model adjustment to obtain a sub-collection of the model architecture collection. The target attribute can include one attribute or a combination of a plurality of attributes. The target operation can include one architecture operation or a combination of the plurality of architecture operations.

The attribute values of the target attributes of the seed model architectures can be adjusted based on the pre-determined adjustment strategy, and/or the target operation can be applied to the seed model architectures based on the pre-determined operation strategy to obtain the non-seed model architectures of the seed model architectures corresponding to the target attributes and/or the target operation.

The seed model architectures and the non-seed model architectures of the seed model architectures corresponding to the target attributes and/or the target operation can form a sub-collection of the model architecture collection. The non-seed model architectures of different sub-collections can correspond to different target attributes and/or different target operations.

In some embodiments, the plurality of seed model architectures can correspond to different specifications, and the corresponding specifications can be in a discrete distribution state. The sub-collection of the model architecture collection can include the plurality of seed model architectures and the non-seed model architectures corresponding to different specifications. The corresponding specifications can be in a continuous distribution state.

In some embodiments, the model constraint condition can be used to indicate the target specification required by the model architecture.

The first determination unit 602 can be configured to determine the model architectures with matching degree between the corresponding specifications and the target specification indicated by the model constraint condition belonging to the first k matching degrees in the matching degree descending sequence from the model architecture collection to obtain the k target model architectures. k can be an integer not smaller than 1.

In some embodiments, the model constraint condition can be used to indicate the target specification required by the model architecture.

The first determination unit 602 can be further configured to obtain the model architecture samples sampled from the current sub-collection and obtain the model architectures included in the current replay pool as the candidate model architectures. The replay pool can be initially empty.

The first determination unit 602 can be further configured to determine the model architectures with the matching degree between the corresponding specifications and the target specification indicated by the model constraint condition belonging to the first I matching degrees in the matching degree descending sequence from the candidate model architectures and update the determined k model architectures to the replay pool. When the replay pool is not empty, the number of the model architectures in the replay pool can be k.

The first determination unit 602 can be further configured to determine a next sub-collection, update the current sub-collection as the next sub-collection, and switch to the step of obtaining the model architecture samples sampled from the current sub-collection and obtaining the model architectures included in the current replay pool as the candidate model architectures to iterate and update the model architectures in the replay pool until the model architectures in the replay pool satisfying the iteration ending condition are used as the target model architectures.

In some embodiments, when the target model architecture is the non-seed model architecture, the second determination unit 603 can be configured to determine the model architecture satisfying a matching condition with the target model architecture from the seed model architectures as the reference model architecture and determine the pre-trained model parameter of the target model architecture based on the pre-trained model parameter of the reference model architecture.

In some embodiments, when determining the model architecture satisfying the matching condition with the target model architecture from the seed model architectures as the reference model architecture, the second determination unit 603 can be configured to determine the seed model architecture with the corresponding specification closest to the specification of the target model architecture from the seed model architectures as the reference model architecture.

In some embodiments, when determining the pre-trained model parameter of the target model architecture based on the pre-trained model parameter of the reference model architecture, the second determination unit 603 can be further configured to determine the correspondence between the layer sets of the target model architecture and the layer sets of the reference model architecture according to the size of the output layer feature image. A layer set of the model architecture can be a combination of a plurality of functional layers in the model architecture capable of completing one sampling.

the second determination unit 603 can be further configured to determine the correspondence between different functional layers of the corresponding layer sets of the target model architectures and the reference model architecture and determine the layer weight of the functional layer of the target model architecture according to the layer weight of the functional layer of the target model architecture in the corresponding functional layer of the corresponding layer set of the reference model architecture. The layer weights of the functional layers of different layer sets of the target model architecture can form the pre-trained model parameters of the target model architecture.

For the processing apparatus of embodiments of the present disclosure, since apparatus embodiments correspond to method embodiments of the present disclosure, the description of the processing apparatus can be simple. For the relevant description, reference can be made to method embodiments of the present disclosure, which is not described in detail.

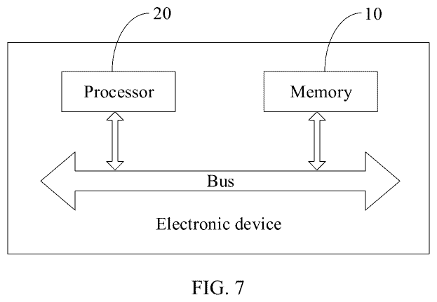

Embodiments of the present disclosure further provide an electronic device. As shown in FIG. 7, the electronic device includes a memory 10 and a processor 20.

The memory 10 can be used to store a computer instruction set.

The computer instruction set can be implemented as a computer program.

The processor 20 can be configured to perform the computer instruction set to implement the processing method of the present disclosure.

The processor 20 can include a central processing unit (CPU), an application-specific integrated circuit (ASIC), a digital signal processor (DSP), a field programmable gate array (FPGA), or another programmable logic device.

The electronic device can include a display apparatus and/or a display interface capable of being connected to an external display apparatus.

In some embodiments, the electronic device can further include a camera assembly and/or an external camera assembly.

In addition, the electronic device can further include a communication interface and a communication bus. The memory, the processor, and the communication interface can communicate with each other through the communication bus.

The communication interface can be configured for communication between the electronic device and other devices. The communication bus can be a peripheral component interconnect (PCI) bus of an extended industry standard architecture (EISA) bus. The communication bus can include an address bus, a data bus, or a control bus.

In summary, the processing method, apparatus, and electronic device of embodiments of the present disclosure can at least include the following advantages.
a) Any model structures including existing classical models can be used to create an automatic model group using the method of the present disclosure.
b) When the user model constraint condition is satisfied, The automatic model search process is faster by one to two orders of magnitude compared to the existing method.
c) With the given constraint condition such as the determined model parameter quantity and the determined computation power, the target model architecture with the pre-trained weight is provided in the method of the present disclosure.
d) The labeled data amount required by the downstream task training is greatly reduced with the obtained model to accelerate the downstream application.

Various embodiments of the present disclosure are described in a progressive manner. Each embodiment focuses on the differences from other embodiments, and the common and similar parts among the various embodiments can be cross-referenced.

To facilitate the description, when the system or device is described, the modules or units divided according to functions can be described separately. When the present disclosure is implemented, the functions of the units can be implemented in one or more pieces of software and/or hardware.

Through the description of embodiments of the present disclosure, those skilled in the art can clearly understand that the present disclosure can be implemented with the assistance of software and a necessary general hardware platform. Based on this understanding, the essence of the technical solution of the present disclosure or the part contributing to the existing technology can be embodied in the form of a software product. The computer software product can be stored in a storage medium such as ROM/RAM, disk, optical disc, etc., and include multiple instructions to cause a computer device (e.g., a personal computer, server, or network device, etc.) to execute the methods of various embodiments or certain parts of the embodiments of the present disclosure.

Finally, terms such as “first,” “second,” “third,” and “fourth” are only used to distinguish one entity or operation from another, and do not necessarily imply any actual relationship or order between these entities or operations. Moreover, the terms “comprise,” “include,” or any other variants are intended to cover non-exclusive inclusion, such that a process, method, item, or device including a series of elements not only includes those elements explicitly listed but also includes other elements not explicitly listed, or includes elements inherent to such process, method, item, or device. When there is no more limitation, an element defined by the term “comprising a . . . ” does not exclude the presence of additional identical elements in the process, method, item, or device including the element.

The above embodiments are only some embodiments of the present disclosure. For those skilled in the art, various improvements and refinements can be made without departing from the principles of the present disclosure. These improvements and refinements should also be within the scope of the present disclosure.

What is claimed is:

1. A processing method comprising:
obtaining a model constraint condition;
determining at least one target model architecture satisfying the model constraint condition from a constructed model architecture collection, wherein:
the model architecture collection includes at least one seed model architecture with a pre-trained model parameter and a non-seed model architecture without a pre-trained model parameter obtained by adjusting the seed model architecture; and
the target model architecture is one of the seed model architecture or the non-seed model architecture; and
determining a pre-trained model parameter of the target model architecture according to the pre-trained model parameter of the corresponding seed model architecture to identify the target model architecture with the pre-trained model parameter.

2. The method according to claim 1, wherein constructing the model architecture collection includes:
obtaining a plurality of seed model architectures with pre-trained model parameters;
adjusting model attributes of the seed model architectures and/or applying corresponding architecture operations to the seed model architectures to obtain non-seed model architectures corresponding to the seed model architectures, the seed model architectures and the non-seed model architectures corresponding to the seed model architectures forming the model architecture collection.

3. The method according to claim 2, wherein:
the model architecture collection includes a plurality of sub-collections; and
constructing the sub-collections includes:
obtaining the plurality of seed model architectures with the pre-trained model parameters;
determining a target attribute and/or a target operation used for model adjustment to obtain a sub-collection of the model architecture collection, the target attribute including one attribute or a combination of a plurality of attributes, and the target operation including an architecture operation or a combination of a plurality of architecture operations;
adjusting an attribute value of the target attribute of the seed model architectures based on a predetermined adjustment strategy, and/or applying the target operation to the seed model architectures based on a predetermined operation strategy to obtain the non-seed model architectures of the seed model architectures corresponding to the target attribute and/or the target operation;
wherein:
the seed model architectures and the non-seed model architectures of the seed model architectures corresponding to the target attribute and/or the target operation form a sub-collection of the model architecture collection; and
non-seed model architectures of different sub-collections correspond to different target attributes and/or different target operations.

4. The method according to claim 3, wherein:
the plurality of seed model architectures correspond to different specifications, and the corresponding specifications are in a discrete distribution state; and
the plurality of seed model architectures and the non-seed model architectures included in the sub-collection of the model architecture collection correspond to different specifications, and the corresponding specifications are in a continuous distribution state.

5. The method according to claim 1, wherein:
the model constraint condition is used to indicate a target specification required for the model architecture; and
determining the at least one target model architecture satisfying the model constraint condition from the constructed model architecture collection includes:
determining, from the model architecture collection, model architectures with matching degrees between corresponding specifications and the target specification indicated by the model constraint condition belonging to first k matching degrees in a matching degree descending sequence to obtain k target model architectures, k being an integer not smaller than 1.

6. The method according to claim 1, wherein:
the model constraint condition is used to indicate a target specification required for the model architecture; and
determining the at least one target model architecture satisfying the model constraint condition from the constructed model architecture collection includes:
obtaining model architecture samples sampled from a current sub-collection and obtaining model architectures included in a current replay pool as candidate model architectures, the replay pool being empty initially;
determining, from the candidate model architectures, model architectures with matching degrees between the corresponding specifications and the target specification indicated by the model constraint condition belonging to first k matching degrees in a matching degree descending sequence, and updating the k determined model architectures to the replay pool, when the replay pool is not empty, a number of the model architectures in the replay pool being k; and
determining a next sub-collection, updating the current sub-collection to the next sub-collection, and switching to obtaining the model architecture samples sampled from the current sub-collection and obtaining the model architectures included in the current replay pool as the candidate model architectures to iteratively update the model architectures in the replay pool until an iteration ending condition is satisfied and the model architectures in the replay pool are used as the target model architectures.

7. The method according to claim 1, wherein when the target model architecture is a non-seed model architecture, determining the pre-trained model parameter of the target model architecture according to the pre-trained model parameter of the corresponding seed model architecture includes:
determining a model architecture from the seed model architectures that satisfies a matching condition with the target model architecture as a reference model architecture; and
determining the pre-trained model parameter of the target model architecture based on the pre-trained model parameter of the reference model architecture.

8. The method according to claim 7, wherein determining a model architecture from the seed model architectures that satisfies the matching condition with the target model architecture as the reference model architecture includes:
determining a seed model architecture from the seed model architectures with the corresponding specification closest to the specification of the target model architecture as the reference model architecture.

9. The method according to claim 7, wherein determining the pre-trained model parameter of the target model architecture based on the pre-trained model parameter of the reference model architecture includes:
determining a correspondence between layer sets of the target model architecture and layer sets of the reference model architecture based on a size of an output layer feature image, wherein a layer set of a model architecture is a combination of a plurality of functional layers capable of completing one sampling in the model architecture;
determining a correspondence between different functional layers of corresponding layer sets of the target model architecture and the reference model architecture; and
determining layer weights of the functional layers of the target model architecture according to layer weights of the corresponding functional layers in the corresponding layer sets of the reference model architecture of the functional layers of the target model architecture, the layer weights of the functional layers of different layer sets of the target model architecture forming pre-trained model parameters of the target model architecture.

10. An electronic device comprising:
a processor; and
a memory storing at least one computer instruction collection that, when called and executed by the processor, causes the processor to:
obtain a model constraint condition;
determine at least one target model architecture satisfying the model constraint condition from a constructed model architecture collection, wherein:
the model architecture collection includes at least one seed model architecture with a pre-trained model parameter and a non-seed model architecture without a pre-trained model parameter obtained by adjusting the seed model architecture; and
the target model architecture is one of the seed model architecture or the non-seed model architecture; and
determine a pre-trained model parameter of the target model architecture according to the pre-trained model parameter of the corresponding seed model architecture to identify the target model architecture with the pre-trained model parameter.

11. The device according to claim 10, wherein the processor is further configured to:
obtain a plurality of seed model architectures with pre-trained model parameters;
adjust model attributes of the seed model architectures and/or apply corresponding architecture operations to the seed model architectures to obtain non-seed model architectures corresponding to the seed model architectures, the seed model architectures and the non-seed model architectures corresponding to the seed model architectures forming the model architecture collection.

12. The device according to claim 11, wherein:
the model architecture collection includes a plurality of sub-collections; and
the processor is further configured to:
obtain the plurality of seed model architectures with the pre-trained model parameters;
determine a target attribute and/or a target operation used for model adjustment to obtain a sub-collection of the model architecture collection, the target attribute including one attribute or a combination of a plurality of attributes, and the target operation including an architecture operation or a combination of a plurality of architecture operations;
adjust an attribute value of the target attribute of the seed model architectures based on a predetermined adjustment strategy, and/or applying the target operation to the seed model architectures based on a predetermined operation strategy to obtain the non-seed model architectures of the seed model architectures corresponding to the target attribute and/or the target operation;
wherein:
the seed model architectures and the non-seed model architectures of the seed model architectures corresponding to the target attribute and/or the target operation form a sub-collection of the model architecture collection; and
non-seed model architectures of different sub-collections correspond to different target attributes and/or different target operations.

13. The device according to claim 12, wherein:
the plurality of seed model architectures correspond to different specifications, and the corresponding specifications are in a discrete distribution state; and
the plurality of seed model architectures and the non-seed model architectures included in the sub-collection of the model architecture collection correspond to different specifications, and the corresponding specifications are in a continuous distribution state.

14. The device according to claim 10, wherein:
the model constraint condition is used to indicate a target specification required for the model architecture; and
the processor is further configured to:
determine, from the model architecture collection, model architectures with matching degrees between corresponding specifications and the target specification indicated by the model constraint condition belonging to first k matching degrees in a matching degree descending sequence to obtain k target model architectures, k being an integer not smaller than 1.

15. The device according to claim 10, wherein:
the model constraint condition is used to indicate a target specification required for the model architecture; and
the processor is further configured to:
obtain model architecture samples sampled from a current sub-collection and obtaining model architectures included in a current replay pool as candidate model architectures, the replay pool being empty initially;
determine, from the candidate model architectures, model architectures with matching degrees between the corresponding specifications and the target specification indicated by the model constraint condition belonging to first k matching degrees in a matching degree descending sequence, and updating the k determined model architectures to the replay pool, when the replay pool is not empty, a number of the model architectures in the replay pool being k;
determine a next sub-collection, update the current sub-collection to the next sub-collection, and switch to obtaining the model architecture samples sampled from the current sub-collection and obtaining the model architectures included in the current replay pool as the candidate model architectures to iteratively update the model architectures in the replay pool until an iteration ending condition is satisfied and the model architectures in the replay pool are used as the target model architectures.

16. The device according to claim 10, wherein when the target model architecture is a non-seed model architecture, the processor is further configured to:
determine a model architecture from the seed model architectures that satisfies a matching condition with the target model architecture as a reference model architecture; and
determine the pre-trained model parameter of the target model architecture based on the pre-trained model parameter of the reference model architecture.

17. The device according to claim 16, wherein the processor is further configured to:
determine a seed model architecture from the seed model architectures with the corresponding specification closest to the specification of the target model architecture as the reference model architecture.

18. The device according to claim 16, wherein the processor is further configured to:
determine a correspondence between layer sets of the target model architecture and layer sets of the reference model architecture based on a size of an output layer feature image, wherein a layer set of a model architecture is a combination of a plurality of functional layers capable of completing one sampling in the model architecture;
determine a correspondence between different functional layers of corresponding layer sets of the target model architecture and the reference model architecture; and
determine layer weights of the functional layers of the target model architecture according to layer weights of the corresponding functional layers in the corresponding layer sets of the reference model architecture of the functional layers of the target model architecture, the layer weights of the functional layers of different layer sets of the target model architecture forming pre-trained model parameters of the target model architecture.

19. A computer readable storage medium storing a computer instruction set that, when executed by a processor, causes the processor to:
obtain a model constraint condition;
determine at least one target model architecture satisfying the model constraint condition from a constructed model architecture collection, wherein:
the model architecture collection includes at least one seed model architecture with a pre-trained model parameter and a non-seed model architecture without a pre-trained model parameter obtained by adjusting the seed model architecture; and
the target model architecture is one of the seed model architecture or the non-seed model architecture; and
determine a pre-trained model parameter of the target model architecture according to the pre-trained model parameter of the corresponding seed model architecture to identify the target model architecture with the pre-trained model parameter.

20. The computer readable storage medium according to claim 19, wherein the processor is further configured to:
obtain a plurality of seed model architectures with pre-trained model parameters;
adjust model attributes of the seed model architectures and/or apply corresponding architecture operations to the seed model architectures to obtain non-seed model architectures corresponding to the seed model architectures, the seed model architectures and the non-seed model architectures corresponding to the seed model architectures forming the model architecture collection.
